(19) United States
(12) Patent Application Publication
(10) Pub. No.: US 2025/0166714 A1
(43) Pub. Date: May 22, 2025

(54) SEMICONDUCTOR DEVICE, OPERATION METHOD THEREOF, AND STORAGE SYSTEM

(71) Applicant: Wuhan Xinxin Semiconductor Manufacturing Co., Ltd., Wuhan (CN)

(72) Inventor: Yan Qiang DU, Wuhan (CN)

(73) Assignee: Wuhan Xinxin Semiconductor Manufacturing Co., Ltd., Wuhan (CN)

(21) Appl. No.: 18/935,729

(22) Filed: Nov. 4, 2024

(30) Foreign Application Priority Data
Nov. 16, 2023 (CN) 202311546094.8

(51) Int. Cl. G11C 16/30

(52) U.S. Cl. CPC G11C 16/30

(57) ABSTRACT

A semiconductor device includes: a reference voltage circuit configured to generate a reference voltage; a charge pump configured to generate an output voltage based on the reference voltage; a charge pump detection circuit configured to detect the output voltage of the charge pump; and a power consumption control circuit configured to disable the reference voltage circuit for a first time period.

### CROSS-REFERENCE TO RELATED APPLICATION

This application claims the benefit of priority of Chinese Patent Application No. 202311546094.8, filed on Nov. 16, 2023, the contents of which are incorporated by reference as if fully set forth herein in their entirety.

### TECHNICAL FIELD

The present application relates to a field of semiconductor devices, and more particularly, to a semiconductor device, an operation method thereof, and a storage system.

### BACKGROUND

A charge pump circuit is a DC-DC circuit that may generate a higher module operating voltage than the source voltage, and is particularly widely applied in non-volatile memories. For example, the charge pump circuit may generate higher programming and erasing voltages for floating-gate devices within EEPROM and flash memories.

A flash memory has a data storage function, and includes an NAND-type flash memory and a NOR-type flash memory. However, both the NAND-type flash memory and the NOR-type flash memory have a power consumption problem. The power consumption problem is always an important index of the flash memory, especially for a mobile device powered by a battery. Therefore, how to reduce the power consumption is an urgent problem.

### SUMMARY

In view of the above, an embodiment of the present disclosure provides a semiconductor device including: a reference voltage circuit configured to generate a reference voltage; a charge pump configured to generate an output voltage based on the reference voltage; a charge pump detection circuit configured to detect the output voltage of the charge pump; and a power consumption control circuit configured to disable the reference voltage circuit for a first time period.

An embodiment of the present disclosure provides a method of operating a semiconductor device including: generating a reference voltage by a reference voltage circuit; generating an output voltage by a charge pump according to the reference voltage; and detecting the output voltage of the charge pump and disabling the reference voltage circuit for a first time period.

An embodiment of the present disclosure further provides a display panel including: a semiconductor device described above; and a controller configured to control the semiconductor device.

### BRIEF DESCRIPTION OF THE DRAWINGS

In order to more clearly illustrate technical solutions in embodiments of the present disclosure, the accompanying drawings depicted in the description of the embodiments will be briefly described below. It will be apparent that the accompanying drawings in the following description are merely some embodiments of the present disclosure, and other drawings may be obtained from these drawings without creative effort by those skilled in the art.

FIG. 1 shows a schematic block diagram of an exemplary memory according to embodiments of the present application.

FIG. 2 shows a schematic block diagram of a voltage generator in the memory of FIG. 1.

FIG. 3A shows a schematic block diagram of a voltage generator in the memory of FIG. 2.

FIG. 3B shows a timing diagram of voltages related to the voltage generator shown in FIG. 3A.

FIG. 4A shows a schematic block diagram of another voltage generator in the memory of FIG. 2.

FIG. 4B shows a timing diagram of voltages related to the voltage generator shown in FIG. 4A.

FIG. 5 shows a flowchart of the operation method of the semiconductor device according to the embodiment of the present application.

FIG. 6 is a block diagram of a memory system according to an embodiment of the present application.

### DETAILED DESCRIPTION

Technical solutions in embodiments of the present application will be clearly and completely described below in conjunction with accompanying drawings in the embodiments of the present application. It will be apparent that the embodiments described are merely part of, but not all of, the embodiments of the present application. According to the embodiments of the present application, all other embodiments obtained by those skilled in the art without creative work fall within the scope of the present application.

In the description of the present application, it should be understood that orientations or position relationships indicated by the terms “upper”, “lower”, or the like are based on orientations or position relationships illustrated in the drawings. The terms are used to facilitate and simplify the description of the present application, rather than indicate or imply that the devices or elements referred to herein are required to have specific orientations or be constructed or operate in the specific orientations. Accordingly, the terms should not be construed as limiting the present disclosure. In addition, the term “first”, “second” are for descriptive purposes only and are not to be construed as indicating or imposing a relative importance or implicitly indicating the number of technical features indicated. Thus, a feature that limited by “first”, “second”, or the like may expressly or implicitly include one or more of the features. In the description of the present application, the meaning of “plural/plurality” is two or more, unless otherwise specifically defined.

Reference numerals and/or reference symbols may be repeated in different implementations in the present application, such repetition is for purposes of simplicity and clarity, without itself indicating the relationship between the various implementations and/or arrangements discussed.

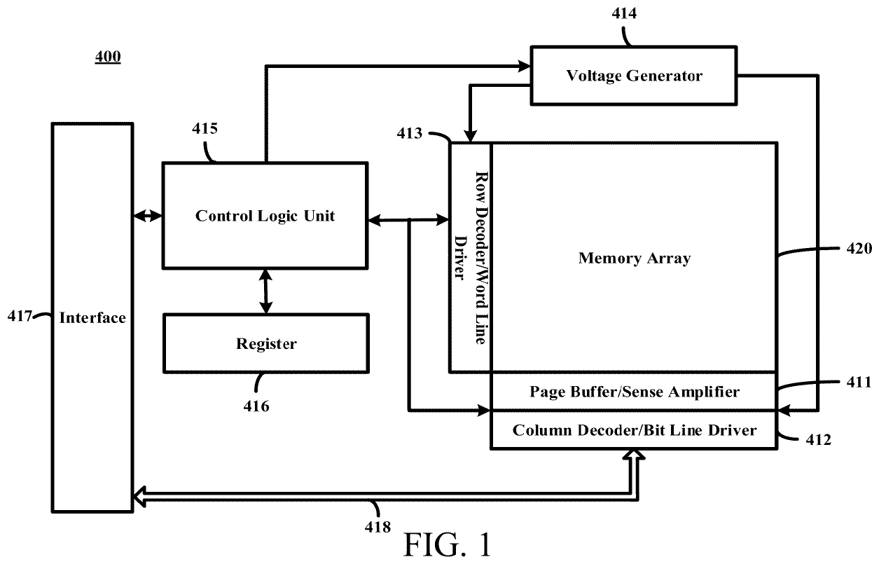

Referring to FIG. 1, FIG. 1 shows a schematic block diagram of a semiconductor device with a memory 400 as an exemplary semiconductor device according to some embodiments of the present application. The memory 400 includes a memory array 420 and other peripheral circuitries (not numbered). As shown in FIG. 1, the peripheral circuitry may include at least elements other than memory array 420, such as page buffer/sense amplifier 411, column decoder/bit line driver 412, row decoder/word line driver 413, voltage generator 414, control logic unit 415, register 416, interface 417, and data bus 418, or the like. It should be understood that in some examples, the peripheral circuitry may also include other circuitry not shown in FIG. 1.

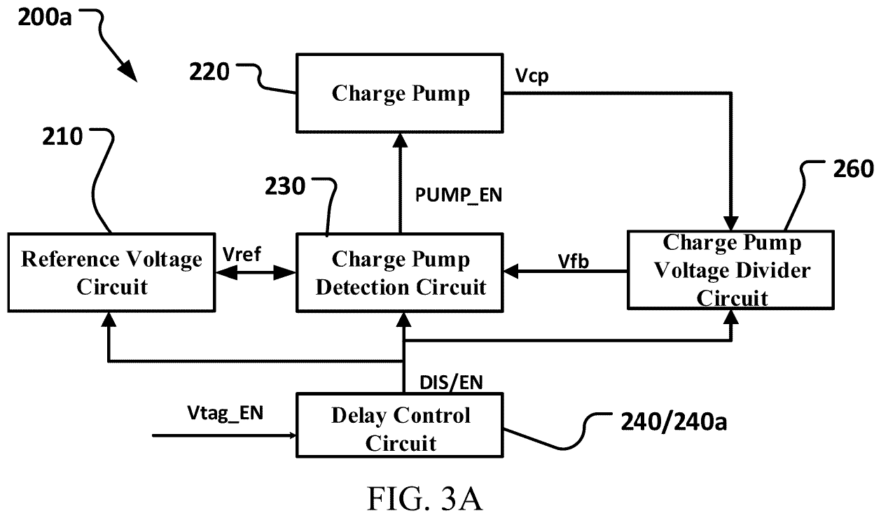

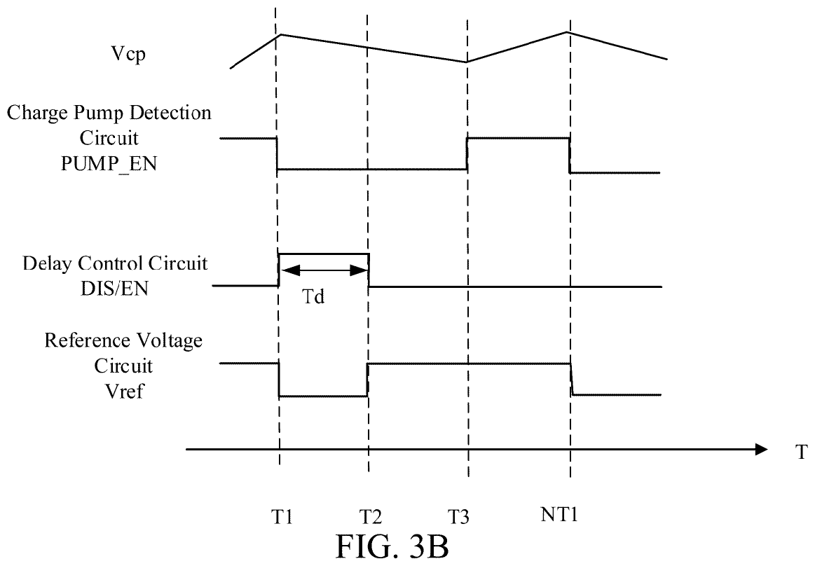

The block diagram shown in FIG. 1 may be applied to, for example, two-dimensional or three-dimensional flash memory (NAND/NOR flash) or memory (DRAM), with the difference being that the memory arrays 420 differ. Thus, the memory array 420 may be a memory array such as a two-dimensional or three-dimensional flash memory (NAND/NOR flash) or memory (DRAM) memory, and the memory may include DRAM, PCRAM, FeRAM, MRAM, and the like. The memory array 420 has at least one large-sized block-like memory platform (Giant Block, GB) including at least a plurality of memory units arranged in an array (see FIGS. 3A and 3B). The plurality of memory units may be appropriately arranged according to a two-dimensional or three-dimensional structure, or may be appropriately arranged according to a NAND, NOR, DRAM architecture.

The page buffer/sense amplifier 411 may be configured to read data from and program (also referred to as “write”) data to the memory array 420 based on control signals from the control logic unit 415. Specifically, in one example, the page buffer/sense amplifier 411 may store data to be programmed to a memory page of memory array 420. In yet another example, the page buffer/sense amplifier 411 may further perform an operation of sensing a low power signal representing data stored in the memory unit from a bit line BL and amplifying a less amplitude of the low power signal to an identifiable logic level in a read operation. The page buffer/sense amplifier 411 may be arranged and combined differently according to the type of the memory array 420 and the design of the bit line BL. For example, the page buffer/sense amplifier 411 may include a plurality of page buffers/sense amplifiers 411 cooperating with a plurality of groups of bit lines.

The column decoder/bit line driver 412 may be configured to be controlled by the control logic unit 415 and to select one or more columns of the memory units by applying a bit line voltage generated from the voltage generator 414. The column decoder/bit line driver 412 may be arranged and combined differently according to the type and the design of the memory array 420. For example, the column decoder/bit line driver 412 may include a plurality of groups of column decoder/bit line drivers 412.

The row decoder/word line driver 413 may be configured to be controlled by the control logic unit 415 to select different memory units in the memory array 420. The row decoder/word line driver 413 may further be configured to drive the word line WL by using the word line voltage generated from the voltage generator 414. The row decoder/word line driver 413 may be arranged and combined differently according to the type and the design of the memory array 420. For example, the row decoder/word line driver 413 may include a plurality of groups of row decoder/word line drivers 413.

Therefore, a charge pump is included in the voltage generator 414, and the voltage generator 414 may be configured to be controlled by the control logic unit 415, and to generate a word line voltage and a bit line voltage to be supplied to the memory array 420 and a current required by the memory array 420.

The control logic unit 415 may be coupled to and control the operation of, each of the peripheral circuits 410 (e.g., the page buffer/sense amplifier 411, the column decoder/bit line driver 412, the row decoder/word line driver 413, and the voltage generator 414) as described above.

The register 416 may be coupled to the control logic unit 415 and may include at least a status register, a command register, and an address register to store status information, an operation code (OP code), and an address for controlling the operation of each of the above circuits.

The interface 417 may be coupled to the control logic unit 415 and be used as a control buffer to perform operations of controlling commands received from the controller of FIG. 1 and relaying the commands to the control logic unit 415, and to perform operations of buffering status information received from the control logic unit 415 and relaying the commands (the status information) to an external controller (not shown). Further, the interface 417 may further be coupled to the column decoder/bit line driver 412 via the data bus 418 and used as a data input/output (I/O) interface and data buffer to perform operations of buffering data and relaying the data to memory array 420, and to perform operations of relaying or buffering data from memory array 420.

In some embodiments, the memory array 420 may be a NOR-type or NAND-type flash memory architecture, or may be, for example, a 1T1C or 1TXC-type memory architecture (“T” represents a transistor, “C” represents a capacitive memory unit, and “X” represents the number). In addition, the memory array may be a 2D architecture or a 3D architecture. These architectures are known to those skilled in the art and not described in more detail herein. These architectures are not intended to limit the scope of the present application, and are within the scope of the present application as long as the technical concepts of the present application may be applied thereto.

In a standby mode of the NOR flash, the control logic unit 415 still generates a voltage higher than zero through the charge pump in the voltage generator 414 and periodically refreshes, which greatly increases the power consumption of the circuit. The power consumption is an important index of various memories, especially for the NOR flash, especially for mobile devices powered by batteries. Therefore, how to reduce read power consumption is an urgent problem. In addition, in the standby mode of the NOR flash, the internal reference voltage circuit is always in an operation state and generates a reference voltage that does not change with the process, voltage, or temperature. With this reference voltage, the charge pump inside the chip may generate a voltage of an unchanged level higher than the power supply voltage and used for the read operation. The power consumption consumed by the reference voltage circuit and the power consumption generated by the voltage periodically refreshed by the charge pump are two primary parts of the standby power consumption of the NOR flash.

In addition, the above description is an example of an application of the charge pump by using the flash memory as an example, it is understood, however, that there are quite a number of semiconductor devices that the charge pump is applied and the semiconductor devices are not limited to the memory. The memory 400 is only an illustration of an exemplary application of the semiconductor devices provided in the present application. Therefore, the semiconductor device provided in the present application may be the voltage generator 414 itself or the memory 400. Hereinafter, the voltage generator 414 is illustrated merely as an example of the semiconductor device provided in the present application. That is, the semiconductor device 200/200a/200 described below may be used as the voltage generator 414 described above.

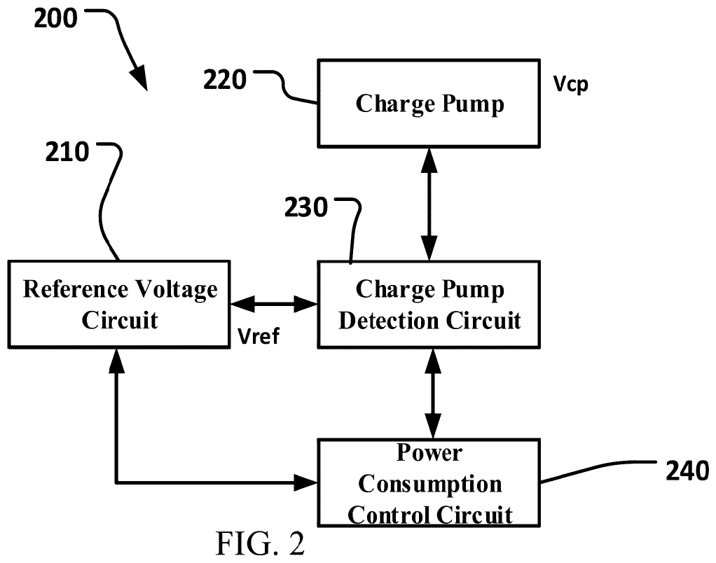

To solve the problem of the power consumption, FIG. 2 shows a schematic block diagram of a semiconductor device 200 as the above voltage generator 414 according to an embodiment of the present application.

As shown in FIG. 2, the semiconductor device 200 according to an embodiment of the present application includes a reference voltage circuit 210 configured to generate a reference voltage; a charge pump 220 configured to generate an output voltage according to the reference voltage; a charge pump detection circuit 230 configured to detect the output voltage of the charge pump; and a power consumption control circuit 240 configured to disable the reference voltage circuit for a first time period.

The reference voltage circuit 210 is one of the common circuit modules in an integrated circuit chip, and almost all types of chips require the reference voltage circuit, so the power consumption of the reference voltage is a part of the power consumption of the chip. In some embodiments, the reference voltage circuit may include a bandgap reference voltage circuit, such as a CMOS bandgap reference voltage circuit, capable of providing not only the reference voltage or current required by the system, but also the advantages of low power consumption, high integration, and ease of design. Therefore, the reference voltage circuit is widely used in analog integrated circuits and hybrid integrated circuits. However, in an embodiment of the present application, the following description is provided by taking the reference voltage circuit as an example. The reference voltage circuit 210 provides an accurate reference voltage Vref to the charge pump 220 after the reference voltage circuit 210 is enabled. Since the inventive concept of the present application does not lie in the circuit design of the reference voltage circuit or the bandgap reference voltage circuit 210, the reference voltage circuit 210 is represented in the present application merely by a block diagram, may be implemented from the block diagram by a person skilled in the art, and is not described in detail herein.

The charge pump 220 is a DC-DC circuit that may generate an output voltage Vcp that is higher than the reference voltage Vref described above, as a module operating voltage, and is widely used in the non-volatile memories. For example, the charge pump 220 may generate higher programming and erasing voltages for floating-gate devices within the EEPROM and flash memories. The charge pump 220 includes a capacitor (not shown) as an energy storage element for generating an output voltage Vcp greater than the input voltage, or for generating a negative output voltage Vcp. The charge pump 220 further includes a switching component (not shown) for controlling the voltage connected to the capacitor. For example, a higher pulse voltage is output based on a lower input voltage by using a two-stage cycle. In a first phase of the cycle, the capacitor is connected to the power supply terminal, and is charged to a voltage of a level same as that of the power supply. In the first phase, a connection configuration of the circuit is adjusted so that the capacitor and the power supply voltage are connected in series. If the leakage current effect is omitted and there is no load, the level of the output voltage is twice that of the input voltage (the sum of the levels of the original power supply voltage and the voltage across the capacitor). The pulse characteristics of the higher output voltage Vcp may be filtered by using an output filter capacitor.

The charge pump 220 further includes other circuitry configured to control periodic switching of the switching component, at a switching frequency of tens of kHz to several MHz. The higher switching frequency for refreshing may reduce the number of the capacitors needed, allowing for a relatively small amount of charge to be stored in a relatively shorter time period. Capacitors used in charge pumps are generally referred to as flying capacitor. Furthermore, the output voltage Vcp of the charge pump is related to the load. The greater the resistance of the load, the lower the average voltage. Depending on the control mode and circuit architecture, the charge pump may perform voltage doubling, voltage tripling, voltage inversion, voltage multiplication by a fraction (e.g., ×3/2, ×4/3, ×⅔, etc.), or may perform fast switching between different modes to generate an output voltage Vcp having any level, and cause the level of the output voltage Vcp to reach a target value Vtag. That is, after being enabled, the charge pump 220 may generate the output voltage Vcp of a level that reaches the target value Vtag according to the reference voltage Vref supplied from the reference voltage circuit 210.

Similarly, since the inventive concept of the present application does lie in the circuit design of the charge pump 220, the charge pump 220 is represented in the present application merely by means of a block diagram, may be implemented from the block diagram by a person skilled in the art, and will not be described in detail.

The charge pump detection circuit 230 is configured to detect the output voltage Vcp of the charge pump 220, and may detect the output voltage Vcp by a device such as a resistor, or any other suitable device that may detect the output voltage Vcp.

The power consumption control circuit 240 is configured to disable the reference voltage circuit for a first time period. Specifically, the power consumption control circuit 240 will be described according to some embodiments.

First, as shown in FIG. 3A, in some embodiments, the power consumption control circuit 240 shown in FIG. 2 includes a delay control circuit 240a. The delay control circuit 240a is configured to activate a first time period delay after the level of the output voltage Vcp reaches the target value Vtag, so that the reference voltage circuit 210 is disabled during the first time period Td.

Specifically, the delay control circuit 240a may be any suitable delay circuit, such as an RC delay circuit, a counter delay circuit, or the like. Similarly, since the inventive concept of the present application does lie in the circuit design of the delay control circuit 240a, the delay control circuit 240a is represented in the present application merely by means of a block diagram, may be implemented from the block diagram by a person skilled in the art, and will not be described in detail.

After the level of the output voltage Vcp of the charge pump 220 reaches the preset target value Vtag, the delay control circuit 240a starts timing in response to an enable signal Vtag_EN output by the charge pump detection circuit 230, and generates a disable signal DIS to the reference voltage circuit 210, so that the reference voltage circuit 210 is disabled during the first time period Td of the timing in response to the disable signal DIS. When the reference voltage circuit 210 is disabled and cannot generate the reference voltage Vref, the charge pump 220 is also disabled.

In some embodiments, the delay control circuit 240a generates an enable signal EN to enable the reference voltage circuit 210 after the delay time Td has elapsed, that is, after the delay time ends, and detects whether the output voltage Vcp satisfies a requirement through the charge pump detection circuit 230 after the second time period from the timing T2 to the timing T3 has elapsed.

Specifically, as shown in FIG. 3B, FIG. 3B shows a timing diagram of voltages related to the semiconductor device 200a shown in FIG. 3A. In FIG. 3B, the timing T1 represents a timing when the level of the output voltage Vcp of the charge pump 220 reaches the target value Vtag, the first time period delay Td starts, and the reference voltage Vref is not generated by the reference voltage circuit 210. The timing Td is the duration from the timing T1 to the timing T2. The time delay control circuit 240a transmits the disable signal DIS at a rising edge at the timing T1 to disable the reference voltage circuit 210 and the charge pump 220. After the first time period Td has elapsed, the time delay control circuit 240a transmits the enable signal EN at a falling edge at the timing T2 to enable the reference voltage circuit 210. It is to be understood that time intervals between any two of the time timings T1/T2/T3 or the like in the figures do not represent an actual time, but are merely intended to represent the order of the time timings. The waveforms shown are schematic and do not represent actual rising and falling speeds.

In some embodiments, it may take a time period for the reference voltage circuit 210 to resume normal and stable operation. Therefore, the charge pump 220 may resume normal and stable operation after the level of the reference voltage Vref reaches the preset value, that is, after the second time period from the timing T2 to the timing T3 has elapsed. Since the charge pump detection circuit 230 is configured to detect the output voltage Vcp of the charge pump 220, the charge pump detection circuit 230 may suspend operation thereof when the charge pump 220 is disabled. In some embodiments, the charge pump 220 and the charge pump detection circuit 230 may be enabled in response to the enable signal EN from the delay control circuit 240a at the timing T2, like the reference voltage circuit 210. The present application is not limited herein. Further, in some embodiments, the enable signal EN may further be transmitted to the charge pump voltage divider circuit 260 shown in FIG. 3A. Further, the charge pump detection circuit 230 may be controlled by the enable signal EN of the delay control circuit 240a, and the enable signal EN may be transmitted to the charge pump detection circuit 230 at the timing T3, which is not shown in FIG. 3B.

FIG. 3B further shows the variation of the output voltage Vcp of the charge pump 220 at the timings T1, T2, T3. That is, at the timing T1, the level of the output voltage Vcp reaches the target value Vtag, the reference voltage circuit 210 and the charge pump 220 are enabled, and the output voltage Vcp gradually decreases according to the load. The charge pump 220 is enabled again at the timing T3. The level of the output voltage Vcp reaches the target value Vtag at the timing NT1, and the delay in another period is activated.

Further, in some embodiments, the charge pump detection circuit 230 is further configured to disable the reference voltage circuit 210 and the charge pump 220 and activate the first time period delay Td when it is detected that the level of the output voltage Vcp is not less than a preset value Vmin.

In some embodiments, the charge pump detection circuit 230 is further configured to enable the reference voltage circuit 210 when it is detected that the level of the output voltage Vcp of the charge pump 220 is less than the preset value Vmin, and enables the charge pump 220.

Specifically, in some embodiments, the charge pump detection circuit 230 may be configured to continuously detect the output voltage Vcp of the charge pump 220 for a longer time, or discontinuously detect the output voltage Vcp of the charge pump 220. In the case of the discontinuity detection, when it is detected that the level of the output voltage Vcp is not less than the preset value Vmin, the charge pump detection circuit 230 may be configured to continuously disable the reference voltage circuit 210 and the charge pump 220, activate the first time period delay, and a new cycle starts, so that the disabling of the reference voltage circuit 210 in the first time period Td is repeated. The discontinuity duration may be predetermined.

In the case of the continuous detection, the reference voltage circuit 210 and the charge pump 220 may be continuously disabled, but the delay is not activated, when the level of the output voltage Vcp is not less than the preset value Vmin. After the reference voltage circuit 210 and the charge pump 220 are enabled in response that the level of the output voltage Vcp is less than the preset value Vmin and are then disabled in response that the level of the output voltage Vcp reaches the target value Vtag, the first time period delay Td may be activated.

In some embodiments, the first time period Td may last for a longer time period. For example, the first time period Td may last for a plurality of detection cycles of the charge pump detection circuits, or the first time period Td may end after the charge pump a plurality of enable periods and disable periods (on-off cycles) duration of the first time period. It will be appreciated that in a period when the charge pump 220 has experienced a plurality of on-off cycles (such as N on-off cycles, N is greater than or equal to one), the reference voltage circuit 210 has experienced one cycle, because the leakage current of the reference voltage circuit 210, in particular, the bandgap reference voltage circuit, is less than the leakage current of the charge pump. With the configuration of the delay control circuit 240a described above, in the standby mode, by periodically enabling the reference voltage circuit 210 and the charge pump 220, that is, periodically refreshing each of the reference voltage Vref and the output voltage Vcp, a lower power consumption in the standby mode may be obtained, thereby achieving a power consumption control purpose. In addition, the charge pump detection circuit 230 is configured to detect the voltage of the reference voltage circuit 210, and thus the reference voltage detection circuit is omitted, so that the chip area may be reduced and the power consumption may be reduced.

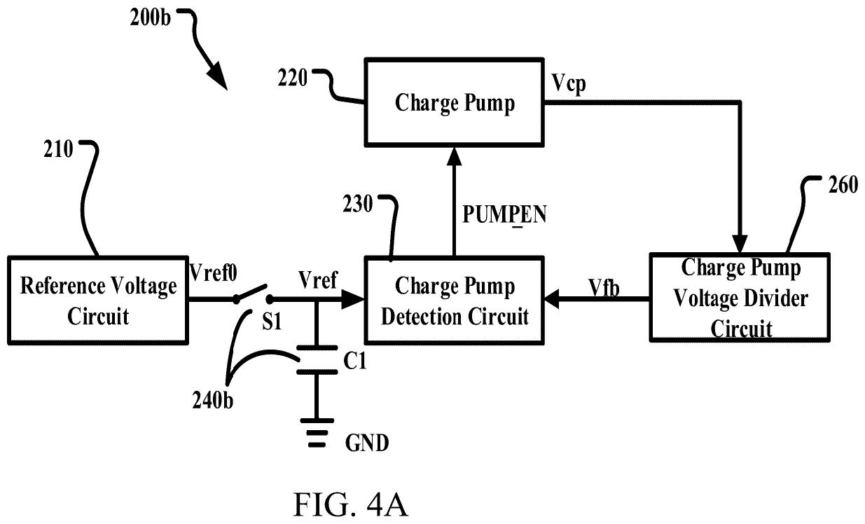

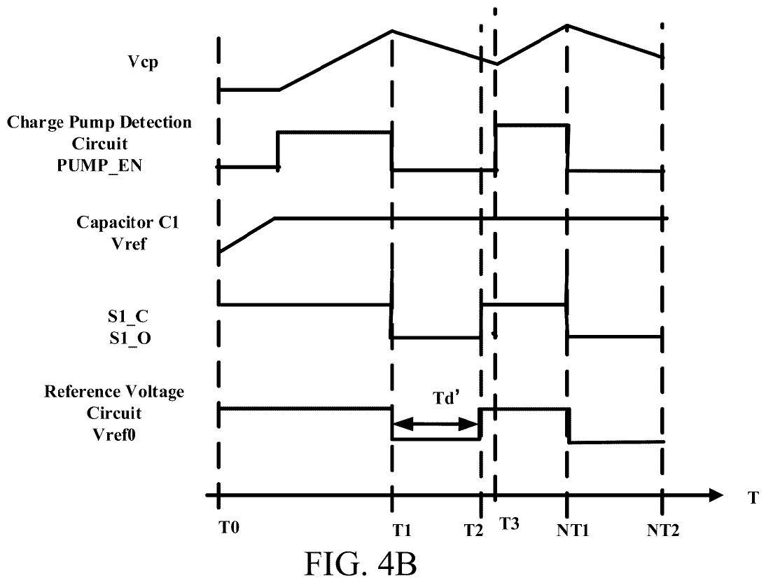

First, as shown in FIG. 4A, in some embodiments, the power consumption control circuit shown in FIG. 2 includes an energy storage circuit 240b. That is, according to other embodiments of the present application, as shown in FIG. 4A, the semiconductor device 200b according to an embodiment of the present application includes a reference voltage circuit 210 configured to generate a reference voltage; a charge pump 220 configured to generate an output voltage according to the reference voltage; a charge pump detection circuit 230 configured to detect the output voltage of the charge pump; and an energy storage circuit 240b configured to disable the reference voltage circuit 210 and start to maintain the level of the reference voltage Vref upon the level of the output voltage Vcp reaching the target value Vtag.

The semiconductor device 200b shown in FIG. 4A differs from the semiconductor device 200a shown in FIG. 3A in the power consumption control circuit 240. That is, the delay control circuit 240a shown in FIG. 3A is used as an example of the power consumption control circuit 240 shown in FIG. 2, and the energy storage circuit 240b shown in FIG. 4A is used as another example of the power consumption control circuit 240 shown in FIG. 2. The other elements such as the reference voltage circuit 210, the charge pump 220, the charge pump detection circuit 230, and the charge pump voltage dividing circuit 260 in FIG. 4A is the same as FIG. 3A. Therefore, in the embodiment shown in FIG. 4A, a repeated description of these components is omitted.

Specifically, as shown in FIG. 4A, the energy storage circuit 240b includes a capacitor C1 and a switch S1 located between the capacitor C1 and the reference voltage circuit 210. The switch S1 is used to disable the reference voltage circuit 210, and disconnect the capacitor C1 and the reference voltage circuit 210 so that the level of the reference voltage Vref is maintained at a level charged by the capacitor C1, after the level of the output voltage Vcp generated by the charge pump 220 reaches the target value Vtag.

In some embodiments, the charge pump detection circuit 230 is further configured to resume operation of the reference voltage circuit 210 and the charge pump 220 and terminate the suspension operation of the reference voltage circuit 210 in the first time period, when it is detected that the level of the output voltage Vcp is less than the preset value Vmin.

Therefore, a time period, from the time when the reference voltage circuit 210 is disabled and the reference voltage Vref is supplied from the capacitor C1 to the time when the level of the output voltage Vcp is less than the preset value so that the reference voltage circuit 210 resumes operation, corresponds to the first time period Td for the time delay of the semiconductor device 200a as shown in FIG. 3B. In other words, with the energy storage circuit 240b, the semiconductor device 200b has a time period Td′ for the time delay corresponding to the first time period Td described above, that is, has a first time period Td′ when the reference voltage circuit 210 is disabled. The present embodiment differs from the above embodiment with reference to FIG. 3B in that duration of the first time period Td′ depends on whether the level of the output voltage Vcp of the charge pump 220, and thus the duration of the first time period Td′ depends on the degree of power consumption of the load of the charge pump 220. It will be appreciated, however, that in some embodiments the amount of power consumption may be dependent not on the degree of power consumption of the load of the charge pump 220, but on the degree of leakage of the charge pump 220 itself, or various other possible factors.

In some embodiments, the charge pump detection circuit 230 is further configured to enable the reference voltage circuit 210 when it is detected that the level of the output voltage Vcp of the charge pump 220 is less than the preset value Vmin (as in the timing T2), and enable the charge pump 220 at the third time period T3 (i.e., after the level of the reference voltage Vref becomes unchanged) after the switch S1 is turned on.

In some embodiments, the reference voltage circuit 210 and the charge pump 220, the charge pump detection circuit 230, and the switch S1 may be enabled and/or turned on at the same time, rather than enabled or turned on in order.

Further, in some embodiments, the charge pump detection circuit 230 is further configured to disable the reference voltage circuit 210 and the charge pump 220 and turn off the switch S1 when it is determined that the level of the output voltage Vcp reaches the target value Vtag, so that the level of the reference voltage is maintained, and another cycle starts. As shown in FIG. 4B, FIG. 4B shows a timing diagram of voltages related to the semiconductor device 200b shown in FIG. 4A. In FIG. 4B, the timing TO represents a timing when power-on of the reference voltage circuit 210 stars, the original reference voltage Vref0 is generated, the switch S1 is turned on, and the capacitor C1 is charged and the voltage across the capacitor C1 may be used as the reference voltage Vref, and after the level of the reference voltage Verf is substantially unchanged, the charge pump 220 is enabled by the enable signal PUMP_EN to output the output voltage Vcp. The timing T1 represents a timing when the level of the output voltage Vcp of the charge pump 220 reaches the target value Vtag, the reference voltage circuit 210 and the charge pump 220 are disabled, the switch S1 is turned off, and the level of the reference voltage is maintained, and another cycle starts (the time delay of the previous embodiment). It is to be understood that time intervals between any two of the time timings T1/T2/T3 or the like in the figures do not represent an actual time, but are merely intended to represent the order of the time timings. The waveforms shown are schematic and do not represent actual rising and falling speeds.

The level of the output voltage Vcp of the charge pump 220 gradually decreases due to the output voltage Vcp being output to the load. At the timing T2, the charge pump detection circuit 230 detects that the level of the output voltage Vcp is lower than the preset value Vmin, and the charge pump detection circuit 230 enables the reference voltage circuit 210 and the charge pump 220, and makes the reference voltage circuit 210 to complete the disabling in the first time period Td′. In particular, the reference voltage circuit 210 is enabled first to generate an initial reference voltage Vref0, and the switch S1 is turned on meanwhile. Then, the charge pump 220 is enabled at the third timing T3. Therefore, the enable signal PUMP_EN is transmitted at the third timing T3 later than the timing T2, and thus the charge pump 220 is enabled at a timing (i.e., the third timing T3) later than the timing T2.

In some embodiments, the enable signal PUMP_EN of the charge pump detection circuit 230 may be turned on simultaneously with the reference voltage circuit 210 and the switch S1. In this case, a rising edge of the enable signal PUMP_EN in FIG. 4B is at the same timing as the timing T2 (not shown), rather than at the third timing T3 later than the timing T2 as shown in FIG. 4B.

After both the charge pump 220 and the reference voltage circuit 210 are enabled, the level of the output voltage Vcp is increased to reach the target value Vtag. Then the reference voltage circuit 210 and the charge pump 220 are disabled, the switch S1 is turned off, and maintenance of the reference voltage in another cycle is activated at the timing NT1.

In FIG. 4B, the states of the capacitor C1 and the switch S1 at the timings T1 and T2 are shown. S1_C represents that the switch is turned on, and S1_O represents that the switch is turned off. Also, in some embodiments, since the charge pump detection circuit 230 is configured to perform a low voltage detection on the charge pump 220, rather than detecting whether the reference voltage is too low, the reference voltage circuit 210 is refreshed (i.e., enabled) at the time of refresh of the charge pump.

However, it will be appreciated that since the charge pump is more likely to leak current and the reference voltage circuit is less likely to leak current. In some embodiments, the charge pump detection circuit may be further configured to enable the charge pump to be refreshed when it is detected that the level of the output voltage is lower than a preset value, and then to enable the reference voltage circuit to be refreshed when the level of the output voltage is still lower than the preset value, e.g., in a one on-off cycle.

Thus, the first period of time Td′ may last for a long time. For example, the first period of time Td′ lasts for a plurality of detection cycles of the charge pump detection circuit. For example, the first period of time Td′ lasts for a plurality of on-off periods of the charge pump. Therefore, in the same time period, the on-off cycles (refresh frequency) of the charge pump may be more than the on-off cycles of the reference voltage circuit 210. For example, in the same time period, the charge pump has N on-off cycles and the reference voltage circuit has one on-off cycle, where N is a positive integer greater than or equal to one. It will be appreciated that this is because of the less leakage of the reference voltage circuit and the voltage maintenance effect due to the energy storage device 240b.

In some embodiments, the reference voltage circuit is enabled to be refreshed, in a way that the reference voltage circuit has one on-off cycle and the charge pump has N on-off cycles in the same time period, based on the low leakage of the reference voltage, rather than based on the case “the level of the output voltage is lower than a preset value even if the charge pump has been enabled to be refreshed”.

Further, in some embodiments, when the charge pump is in the enabled state, the charge pump detection circuit may also be in the enabled state, but as described above, this detection may be a discontinuity detection or a continuity detection.

Although the switch S1 and the reference voltage circuit 210 controlled by the corresponding control signals described above is not shown in FIG. 4A, it will be appreciated by those skilled in the art that these control signals may be transmitted by the charge pump detection circuit 230, or may be transmitted by, for example, the logic control unit 415 in the memory 400, or other control units in the voltage generator 414 or the semiconductor device 200a/200b. The implementation of the embodiments of the present application may implemented even if the control signals are not specifically shown.

In some embodiments, the semiconductor device 200a/200b further includes a charge pump voltage divider circuit 260 for extracting the output voltage Vcp of the charge pump 220 to the charge pump detection circuit 230. Specifically, as shown in FIGS. 3A and 4A, the charge pump detection circuit 230 may obtain the output voltage Vcp of the charge pump 220 through a charge pump voltage divider circuit 260. The charge pump voltage divider circuit 260 may include a resistive voltage divider, or may be any other device capable of generating a voltage divider. The present application is not limited herein.

As described above, with the configuration of the delay control circuit 240b described above, in the standby mode, by periodically enabling the reference voltage circuit 210 and the charge pump 220, that is, by periodically refreshing each of the reference voltage Vref and the output voltage Vcp, a lower power consumption in the standby mode may be obtained, thereby achieving a power consumption control purpose.

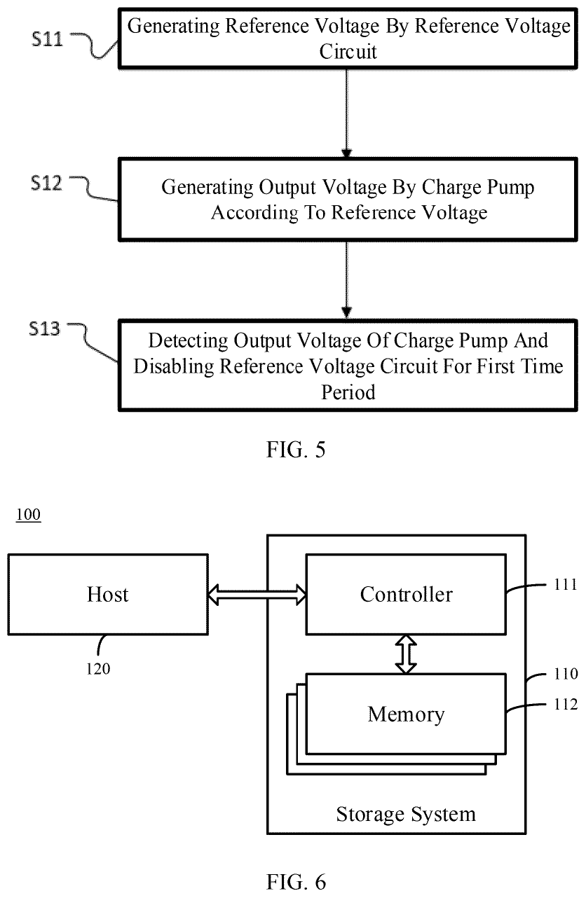

An embodiment of the present application further provides an operation method of the semiconductor device in addition to the semiconductor device exemplified by the memory. As shown in FIG. 5, FIG. 5 shows a flowchart of the operation method of the semiconductor device according to the embodiment of the present application.

An operation method of a semiconductor device according to an embodiment of the present application includes:
generating a reference voltage by a reference voltage circuit (S11);
generating an output voltage by a charge pump according to the reference voltage (S12); and
detecting the output voltage of the charge pump, and disabling the reference voltage circuit for a first time period (S13).

In some embodiments, the disabling of the reference voltage circuit for the first time period includes: activating the first time period delay upon the level of the output voltage Vcp reaching a target value Vtag, so that the reference voltage circuit 210 is disabled for the first time period Td.

In some embodiments, the method further includes: enabling the reference voltage circuit 210 after the first time period delay, and detecting whether the output voltage Vcp meets a requirement through the charge pump detection circuit 230 after a second time period from the timing T2 to the timing T3 has elapsed.

In some embodiments, the method further includes: disabling the reference voltage circuit 210 and the charge pump 220 and activating the first time period delay in response to detecting that a level of the output voltage Vcp is not lower than a preset value by the charge pump detection circuit 230, and keeping the reference voltage circuit 210 in a disabled state until it is determined that the level of the output voltage of the charge pump is lower than a preset value.

In some embodiments, the method further includes: enabling the charge pump 220 in response to detecting that the level of the output voltage Vcp of the charge pump 220 is less than the preset value Vmin by the charge pump detection circuit 230.

In some embodiments, the disabling of the reference voltage circuit for the first time period includes: maintaining the level of the reference voltage Vref by an energy storage circuit 240b, and disabling the reference voltage circuit 210 for the first time period after the level of the output voltage Vcp reaches the target value Vtag.

In some embodiments, the maintaining of the level of the reference voltage by the energy storage circuit includes: receiving and maintaining the level of the reference voltage Vref through a capacitor C1 and a switch S1, and turning off the switch S1 upon the level of the output voltage Vcp reaching the target value Vtag.

In some embodiments, the method further includes: enabling the reference voltage circuit 210 and the charge pump 220 and completing the disabling of the reference voltage circuit in the first time period when it is detected that the level of the output voltage Vcp is lower than a preset value Vmin by the charge pump detection circuit 230.

In some embodiments, when the charge pump detection circuit detects that the level of the output voltage is lower than a preset value, the enabling of the reference voltage circuit and the charge pump includes: enabling the reference voltage circuit 210, and then enabling the charge pump 220 at a third time period after the switch S1 is turned on.

The specific contents of the steps of the above operation methods may be understood with reference to the description of the semiconductor device 200a/200b. Accordingly, reference will not be made here to repeated descriptions, but only the main concepts are provided.

In the operation method of the semiconductor device according to the embodiment of the present application, in the standby mode, by periodically enabling the reference voltage circuit 210 and the charge pump 220, that is, periodically refreshing the reference voltage Vref and the output voltage Vcp, the lower power consumption in the standby mode may be obtained, thereby achieving power consumption control purposes. The reference voltage detection circuit is omitted, so that the chip area may be reduced and the power consumption may be reduced.

Referring to FIG. 6, FIG. 6 is a schematic block diagram of an electronic system 100 including a memory system 110 according to some embodiments of the present application. The electronic system 100 may be, for example, a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having memory therein.

As shown in FIG. 6, the electronic system 100 described above may include at least a storage system 110 and a host computer 120. The storage system 110 includes a controller 111 and one or more memories 112. The memory 112 may be a semiconductor device 400 as described above. The host 120 may be a processor (e.g., central processing unit, CPU) or system on a chip (SoC) of an electronic device (e.g., an application processor, AP). Specifically, the host 120 may be configured to transmit data to or receive data from the memory 112.

According to some embodiments, the controller 111 is coupled to memory 112 and host 120 and is configured to control memory 112. Further, the controller 111 may manage data stored in memory 112 and communicate with host 120. In some embodiments, the controller 111 is designed to operate in a low duty cycle environment, which may be a Universal Serial Bus (USB) flash drive or other medium used in electronic devices such as personal computers, digital cameras, mobile phones, or the like.

The controller 111 may communicate with an external device (e.g., the host 120) in accordance with a particular communication protocol. For example, the controller 111 may communicate with an external device through at least one of various interface protocols, which may include, for example, universal serial bus (USB) protocol, multi media card (MMC) protocol, Peripheral Component Interconnect (PCI) protocol, peripheral component interconnect express (PCI-E) protocol, advanced technology attachment (ATA) protocol, serial ATA protocol, parallel ATA protocol, Small Computer System Interface (SCSI) protocol, enhanced small device interface (ESDI) protocol, integrated drive electronics (IDE) protocol, Firewire protocol, or the like.

Some embodiments of the present application provide a memory system having the same benefits as the memory 112 or semiconductor device 400 described above.

A semiconductor device, an operation method thereof, and a memory system according to an embodiment of the present application. The voltage generator or semiconductor device includes a reference voltage circuit configured to generate a reference voltage; a charge pump configured to generate an output voltage based on the reference voltage; a charge pump detection circuit configured to detect the output voltage of the charge pump; and a power consumption control circuit configured to disable the reference voltage circuit for a first time period. That is, in the standby mode, by periodically enabling the reference voltage circuit 210 and the charge pump 220 or by periodically refreshing the reference voltage Vref and the output voltage Vcp, a lower power consumption in the standby mode may be obtained, thereby achieving the purpose of power consumption control. The reference voltage detection circuit is omitted, so that the chip area may be reduced and the power consumption may be reduced.

In sum, although the present disclosure has been disclosed in the above preferred embodiments, the above preferred embodiments are not intended to limit the present disclosure. Those skilled in the art may make various changes and modifications without departing from the spirit and scope of the present disclosure. Therefore, the scope of the present disclosure is subject to the scope defined in the claims.

What is claimed is:

1. A semiconductor device comprising:
a reference voltage circuit configured to generate a reference voltage;
a charge pump configured to generate an output voltage based on the reference voltage;
a charge pump detection circuit configured to detect the output voltage of the charge pump; and
a power consumption control circuit configured to disable the reference voltage circuit for a first time period.

2. The semiconductor device of claim 1, wherein the power consumption control circuit comprises a delay control circuit configured to activate a first time period delay of the reference voltage circuit upon a level of the output voltage reaching a target value, so that the reference voltage circuit is disabled for the first time period.

3. The semiconductor device of claim 2, wherein the time delay control circuit is configured to enable the reference voltage circuit after the first time period delay is completed, and detect whether the output voltage meets a requirement through the charge pump detection circuit after a second time period has elapsed.

4. The semiconductor device of claim 3, wherein the charge pump detection circuit further configured to disable the reference voltage circuit and the charge pump and activate the first time period delay in response to detecting that the level of the output voltage is not lower than a preset value, and enable the charge pump in response to detecting that the level of the output voltage of the charge pump is lower than a preset value.

5. The semiconductor device of claim 1, wherein the detection of the output voltage by the charge pump detection circuit comprises one of discontinuity detection and continuity detection.

6. The semiconductor device of claim 1, wherein the power consumption control circuit comprises an energy storage circuit configured to disable the reference voltage circuit for the first time period and maintain a level of the reference voltage, upon a level of the output voltage reaching a target value.

7. The semiconductor device of claim 6, wherein the energy storage circuit comprises a capacitor configured to maintain the level of the reference voltage and a switch between the capacitor and the reference voltage circuit, and wherein the switch is configured to disconnect the capacitor and the reference voltage circuit upon the level of the output voltage reaching the target value.

8. The semiconductor device of claim 2, wherein the charge pump detection circuit is further configured to enable the reference voltage circuit and the charge pump when it is detected that the level of the output voltage is lower than a preset value and complete the disabling of the reference voltage circuit in the first time period, or enable the charge pump, after the reference voltage circuit is enabled and the switch is turned on for a third time period.

9. The semiconductor device of claim 2, wherein the charge pump is enabled before the reference circuit is enabled after the first time period is elapsed.

10. The semiconductor device of claim 9, wherein an on-off cycle of the charge pump is performed N times, and an on-off cycle of the reference voltage circuit is performed once, wherein N is a positive integer greater than or equal to one.

11. A method of operating a semiconductor device, comprising:
generating a reference voltage by a reference voltage circuit;
generating an output voltage by a charge pump according to the reference voltage; and
detecting the output voltage of the charge pump and disabling the reference voltage circuit for a first time period.

12. The method of claim 11, wherein the disabling of the reference voltage circuit for the first time period comprises: activate a first time period delay of the reference voltage circuit upon a level of the output voltage reaching a target value, so that the reference voltage circuit is disabled for the first time period.

13. The method of claim 12, further comprising: enabling the reference voltage circuit after the first time period delay, and detecting whether the output voltage meets a requirement through the charge pump detection circuit after a second time period has elapsed.

14. The method of claim 13, further comprising: disabling the reference voltage circuit and the charge pump and activating the first time period delay in response to detecting that the level of the output voltage is not lower than a preset value by the charge pump detection circuit, and keeping the reference voltage circuit in a disabled state until it is determined that the level of the output voltage of the charge pump is lower than a preset value.

15. The method of claim 13, wherein the detecting of the output voltage of the charge pump comprises one of discontinuity detection and continuity detection.

16. The method of claim 11, wherein the disabling of the reference voltage circuit for the first time period comprises: maintaining a level of the reference voltage by an energy storage circuit, and disabling the reference voltage circuit for the first time period after the level of the output voltage reaches the target value.

17. The method of claim 16, wherein the maintaining of the level of the reference voltage by the energy storage circuit comprising: receiving and maintaining the level of the reference voltage through a capacitor and a switch, and turning off the switch upon a level of the output voltage reaching the target value.

18. The method of claim 12, further comprising: enabling the reference voltage circuit and the charge pump in response to detecting that the level of the output voltage is lower than a preset value by the charge pump detection circuit to complete the disabling of the reference voltage circuit in the first time period, or enabling the reference voltage circuit and then enabling the charge pump at a third time period after the switch is turned on.

19. The method of claim 12, further comprising: after the disabling in the first time period, enabling the charge pump before enabling the reference voltage circuit, wherein an on-off cycle of the charge pump is performed N times, and an on-off cycle of the reference voltage circuit is performed once, wherein N is a positive integer greater than or equal to one.

20. A memory system, comprising:
a semiconductor device, wherein the semiconductor device comprising: a reference voltage circuit configured to generate a reference voltage; a charge pump configured to generate an output voltage based on the reference voltage; a charge pump detection circuit configured to detect the output voltage of the charge pump; and a power consumption control circuit configured to disable the reference voltage circuit for a first time period; and
a controller configured to control the semiconductor device.
